(19) United States
(12) Patent Application Publication
(10) Pub. No.: US 2021/0166154 A1
(43) Pub. Date: Jun. 3, 2021

(54) MACHINE LEARNING DEVICE, POWER CONSUMPTION PREDICTION DEVICE, AND CONTROL DEVICE

(71) Applicant: FANUC CORPORATION, Yamanashi (JP)

(72) Inventor: Hideo OGINO, Yamanashi (JP)

(21) Appl. No.: 17/090,128

(22) Filed: Nov. 5, 2020

(30) Foreign Application Priority Data
Nov. 28, 2019 (JP) 2019-215089

(51) Int. Cl. G06N 20/00; G05B 19/4155; G05B 13/02; G01R 21/133

(52) U.S. Cl. CPC G06N 20/00; G05B 19/4155; G05B 2219/37575; G01R 21/133; G05B 2219/49065; G05B 13/0265

(57) ABSTRACT

A learned model is generated which accurately outputs power consumption by running a newly created machining program without performing simulation, and the learned model is utilized to accurately predict the power consumption. A machine learning device includes an input data acquisition unit that, in machining a workpiece with an arbitrary machine tool by running an arbitrary machining program, acquires, as input data, information relating to the machine tool, an auxiliary operation device, and the workpiece, and machining information including the machining program. A label acquisition unit acquires label data indicating power consumption information relating to the machine tool and the auxiliary operation device in the running of the machining program. A learning unit performs supervised learning using the input and label data, and generates a learned model that inputs machining information of machining to be performed and outputs the power consumption information in the machining to be performed.

This application is based on and claims the benefit of priority from Japanese Patent Application No. 2019-215089, filed on 28 Nov. 2019, the content of which is incorporated herein by reference.

### BACKGROUND OF THE INVENTION

### Field of the Invention

The present invention relates to a machine learning device, a power consumption prediction device, and a control device.

### Related Art

Reduction of environmental loads (energy saving, waste reduction, etc.) has become an important issue for companies that possess manufacturing facilities such as machine tools. In order to reduce the environmental load, for example, it is necessary to know the power consumption of manufacturing facilities owned.

In this regard, a technique is known in which a machining program is simulated without actually operating a machine tool, whereby a torque value to be outputted to a machine tool by a numerical control device of the machine tool is calculated by simulation to simulate the power consumption of the machine tool based on the calculated torque value. For example, see Japanese Unexamined Patent Application, Publication No. 2014-219911.

Patent Document 1: Japanese Unexamined Patent Application, Publication No. 2014-219911

### SUMMARY OF THE INVENTION

However, the actual numerical control device modifies a torque command value to be outputted to the machine tool based on feedback from an encoder of a drive unit (servomotor) of the machine tool. On the other hand, in the simulation, since there is no feedback as described above because the machine tool is not moved, the calculated torque value does not necessarily match the torque command value outputted by the actual numerical control device. For this reason, the simulated power consumption has a problem in that the error becomes large as compared with the power consumption of the actual machine tool.

Furthermore, in a case in which a newly created machining program is inputted, it is necessary to predict a machining time by performing simulation again.

Therefore, it is desired to generate a learned model which accurately outputs the power consumption by the operation of a newly created machining program without performing simulation, and to accurately predict the power consumption by utilizing the learned model.

(1) One aspect of a machine learning device according to this disclosure includes: an input data acquisition unit that, in machining of a workpiece with an arbitrary machine tool by running of an arbitrary machining program, acquires, as input data, at least information relating to the machine tool, information relating to an auxiliary operation device that performs an auxiliary operation of the machine tool, information relating to the workpiece, and machining information including the machining program; a label acquisition unit that acquires label data indicating power consumption information relating to power consumption of the machine tool and the auxiliary operation device in the running of the machining program; and a learning unit that performs supervised learning by using the input data acquired by the input data acquisition unit and the label data acquired by the label acquisition unit, and generates a learned model that inputs machining information of machining to be performed and outputs the power consumption information in the machining to be performed.

(2) One aspect of a power consumption prediction device according to this disclosure includes: a learned model that is generated by the machine learning device described in (1), and inputs machining information of machining to be performed and outputs power consumption information in the machining to be performed; an input unit that, prior to running of a machining program, inputs machining information including information relating to a machine tool, information relating to an auxiliary operation device that performs an auxiliary operation of the machine tool, information relating to a workpiece as a machining target, and information relating to the machining program; and a prediction unit that, by inputting the machining information inputted by the input unit to the learned model, predicts power consumption information relating to power consumption at a time of running of the machining program based on the power consumption information in the machining to be performed outputted by the learned model.

(3) One aspect of a control device according to this disclosure includes the power consumption prediction device described in (2).

According to one aspect of the present disclosure, it is possible to generate a learned model that accurately outputs the power consumption by the operation of a newly created machining program without performing simulation. Furthermore, it becomes possible to predict the power consumption by utilizing the learned model.

### BRIEF DESCRIPTION OF THE DRAWINGS

FIG. 1 is a functional block diagram showing a functional configuration example of a prediction system according to an embodiment;

FIG. 2A is a diagram showing an example of machine tool information relating to a machine tool;

FIG. 2B is a diagram showing an example of auxiliary operation information relating to an auxiliary operation device;

FIG. 2C shows an example of a machining program;

FIG. 3 is a diagram showing an example of power consumption information acquired as label data by a label acquisition unit;

FIG. 4 is a diagram showing an example of a learned model to be provided to a power consumption prediction device of FIG. 1;

FIG. 5 is a diagram showing an example of a prediction result by a prediction unit;

FIG. 6 is a flowchart for explaining the prediction processing of the power consumption prediction device in an operation phase;

FIG. 7 is a diagram showing an example of a configuration of the prediction system; and

FIG. 8 is a diagram showing an example of a configuration of the prediction system.

### DETAILED DESCRIPTION OF THE INVENTION

Hereinafter, a description will be given of an embodiment of the present disclosure with reference to the drawings.

### <Embodiment>

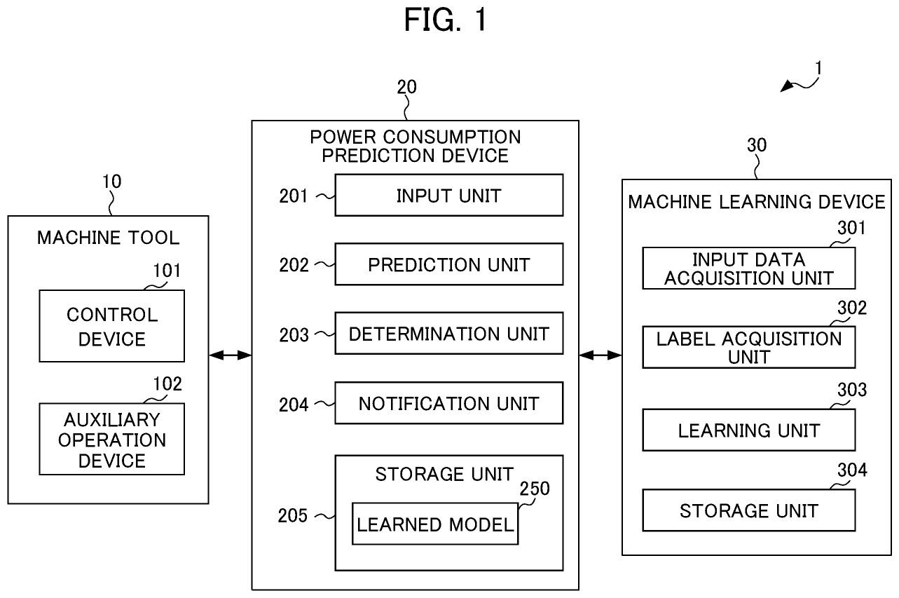

FIG. 1 is a functional block diagram showing a functional configuration example of a prediction system according to an embodiment. As shown in FIG. 1, the prediction system 1 includes a machine tool 10, a power consumption prediction device 20, and a machine learning device 30.

The machine tool 10, the power consumption prediction device 20, and the machine learning device 30 may be directly connected to each other via a connection interface (not shown). Furthermore, the machine tool 10, the power consumption prediction device 20, and the machine learning device 30 may be connected to each other via a network (not shown) such as a local area network (LAN) (Local Area Network) and the Internet. In this case, the machine tool 10, the power consumption prediction device 20, and the machine learning device 30 include a communication unit (not shown) for communicating with each other through the connection. As will be described later, the power consumption prediction device 20 may include the machine learning device 30. The machine tool 10 may also include a power consumption prediction device 20 and a machine learning device 30.

The machine tool 10 is a machine tool known to those skilled in the art, and includes a control device 101 and an auxiliary operation device 102. The machine tool 10 operates based on an operation command of the control device 101. As will be described later, when acquiring a newly created machining program from an external device (not shown) such as a CAD/CAM device, the machine tool 10 may output machining information relating to the machine tool 10 and including the machining program to the power consumption prediction device 20 via a communication unit (not shown) of the machine tool 10 prior to the operation of the acquired machining program.

It should be noted that the information relating to the machine tool 10 included in the machining information may include the number of control axes, the number of spindles, the axis configuration, and the positioning axis/spindle motor specification (rated output (kW), the rated torque (N·m)) or the like. In addition, the machining information may include information relating to the auxiliary operation device 102, which will be described later, such as the pump power (W), the power motor specification (rated output (kW), and the rated torque (N·m)), and information relating to a workpiece (not shown) as a machining target such as the material and the weight.

The control device 101 is a numerical control device known to those skilled in the art. The control device 101 generates an operation command based on a machining program acquired from an external device (not shown), and transmits the generated operation command to the machine tool 10. Thus, the control device 101 controls the operation of the machine tool 10. It should be noted that the control device 101 may output the machining information to the power consumption prediction device 20 instead of the machine tool 10 via the communication unit of the machine tool 10 (not shown).

The control device 101 may also be a device independent of the machine tool 10.

The auxiliary operation device 102 performs the auxiliary operation of the machine tool 10 and is, for example, a hydraulic control device, a coolant pump, a chip conveyor, or the like.

It should be noted that the auxiliary operation device 102 may be a device independent of the machine tool 10. Furthermore, the machine tool 10 may also include a plurality of auxiliary operation devices 102. In this case, the machining information may include information relating to each of the plurality of auxiliary operation devices 102.

The power consumption prediction device 20 acquires machining information relating to the machine tool 10, the auxiliary operation device 102, and the workpiece, and including the machining program, from the machine tool 10 prior to the running of the machining program during the operation phase. Thereafter, the power consumption prediction device 20 inputs the acquired machining information into a learned model provided from the machine learning device 30 to be described later. Thus, the power consumption prediction device 20 can predict the total power consumption amount at the time of the running of the machining program, and the power consumption of each block at the time of the running of the machining program.

Before describing the power consumption prediction device 20, machine learning for generating a learned model will be described.

### <Machine Learning Device 30>

The machine learning device 30 acquires, for example, in advance, as input data, machining information including information relating to the machine tool 10, information relating to the auxiliary operation device 102 for performing auxiliary operation of the machine tool 10, information relating to the machined workpiece, and information relating to a machining program, in the machining of the workpiece with an arbitrary machine tool 10 by the operation of an arbitrary machining program.

Furthermore, the machine learning device 30 acquires, as labels (correct answers), data indicating power consumption information relating to the power consumption of the machine tool 10 and the auxiliary operation device 102 in the running of the machining program based on the acquired input data, that is, the total power consumption amount at the time of the running of the machining program, and the power consumption of each block at the time of the running of the machining program.

The machine learning device 30 performs supervised learning using training data which is a set of the label and the acquired input data, and constructs a learned model to be described later.

In so doing, it is possible for the machine learning device 30 to provide the constructed learned model to the power consumption prediction device 20.

The machine learning device 30 will be described in detail.

As shown in FIG. 1, the machine learning device 30 includes an input data acquisition unit 301, a label acquisition unit 302, a learning unit 303, and a storage unit 304.

In the learning phase, the input data acquisition unit 301 acquires, as input data, machining information including information relating to the machine tool 10, information relating to the auxiliary operation device 102, information relating to the machined workpiece, and information relating to the machining program from the machine tool 10, in machining of the workpiece with an arbitrary machine tool 10 by the operation of an arbitrary machining program through a communication unit (not shown).

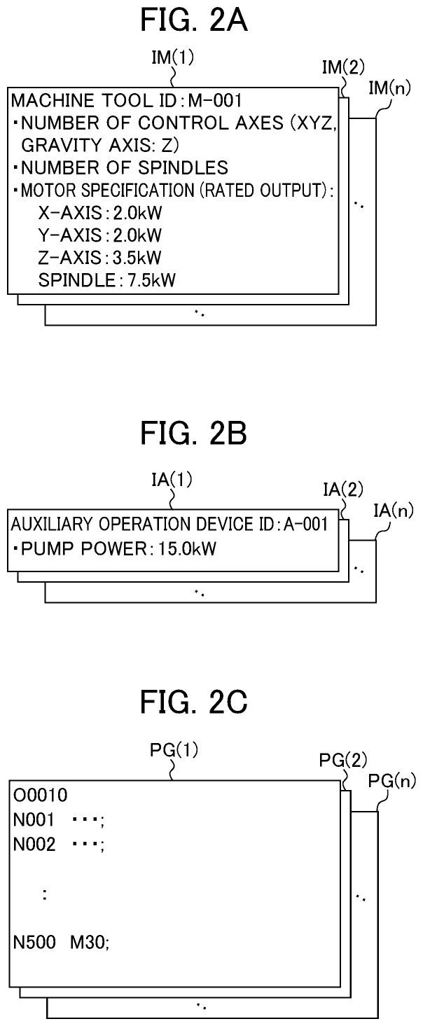

FIG. 2A is a diagram showing an example of machine tool information relating to the machine tool 10.

The input data acquisition unit 301 acquires n pieces of machine tool information IM(1) to IM(n) included in the machining information as input data (n is an integer of 2 or more). As shown in FIG. 2A, the machine tool information IM(1) indicates, for example, that the machine tool 10 is the machine tool ID “M-001” and the number of control axes is “3”. Furthermore, the machine tool information IM(1) indicates that the axis configuration is the orthogonal three axes including the X-axis, Y-axis, and Z-axis, and that the Z-axis is the gravity axis. In addition, the machine tool information IM(1) indicates that the number of spindles of the machine tool 10 is “1”. In addition, the machine tool information IM(1) indicates that the motor specifications (rated output) of the machine tool 10 are “2.0 kW” on the X-axis, “2.0 kW” on the Y-axis, “3.5 kW” on the Z-axis, and “7.5 kW” on the spindle.

In the case of the machine tool 10 being 5 axes, the machine tool information IM(1) is, for example, the number of control axes “5”, the axis configuration is the five axes of X-axis, Y-axis, Z-axis, B-axis and the C-axis, and the Z-axis may indicate that the gravity axis. It should be noted that, when the number of spindles of the machine tool 10 is “1”, the machine tool information IM(1) may indicate that the motor specifications (rated output) of the machine tool 10 is “2.0 kW” on the X axis, “3.0 kW” on the Y axis, “4.5 kW” on the Z axis, “2.5 kW” on the B axis, “2.5 kW” on the C axis, and “8.4 kW” on the spindle.

FIG. 2B is a diagram showing an example of auxiliary operation data relating to the auxiliary operation device 102.

The input data acquisition unit 301 acquires n pieces of auxiliary operation information IA(1) to IA(n) together with the machine tool information IM(1) to IM(n) as input data. As shown in FIG. 2B, the auxiliary operation data IA (1) indicates that, for example, the auxiliary operation device 102 is an auxiliary operation device ID “A-001” and the pumping power is “15.0 kW”. It should be noted that the auxiliary operation information IA(1) may include the rated output of the power motor (for example, 7.5 kW, etc.) as well as the pump power.

FIG. 2C is a diagram showing an example of a machining program.

The input data acquisition unit 301 acquires n pieces of machining programs PG(1) to PG(n) as input data together with the machine tool information IM(1) to IM(n) and the auxiliary operation information IA(1) to IA(n). As shown in FIG. 2C, each of the machining programs PG(1) to PG(n) may include block identification information of a sequence number.

The machining information may include n pieces of workpiece information indicating the material (e.g., FC100) and the weight (e.g., 1.5 kilograms) of the workpiece machined by the machine tool 10 of the machine tool information IM(1) to IM(n) by the operation of each of the machining programs PG(1) to PG(n). The input data acquisition unit 301 may acquire n pieces of workpiece information as input data together with the machine tool information IM(1) to IM(n), the auxiliary operation information IA(1) to IA(n), and the machining programs PG(1) to PG(n).

It should be noted that, in a case of cast iron, examples of the material included in the workpiece information include “FC100”, “FC150”, “FC200”, “FC250”, “FC300”, “FC350”, etc. In addition, in a case of aluminum-alloy, examples of the material included in the workpiece information include “A4032”, “A5052”, “A5083”, “A6061”, and “A7075”. Furthermore, in a case of magnesium-alloy, examples of the material included in the workpiece information include “AZ31”, “AZ91” and the like.

The input data acquisition unit 301 stores the acquired input data in the storage unit 304.

It should be noted that, although the input data includes the information relating to the machine tool 10, the information relating to the auxiliary operation device 102, the information relating to the machined workpiece, and the information relating to the machining program, the input data is not limited thereto and may include at least one of them. Furthermore, instead of the machining program itself being inputted as the input data, the input data may be the contents of the machining program including block specifying information.

The label acquisition unit 302 acquires, as label data (correct answer data), power consumption information relating to the power consumption of the machine tool 10 and the auxiliary operation device 102 in each running of the machining programs PG(1) to PG(n). It should be noted that the power consumption information includes the total power consumption amount of the machine tool 10 and the auxiliary operation device 102 at the time of the running of each of the machining programs PG(1) to PG(n), and the power consumption per block at the time of the running of each of the machining programs PG(1) to PG (n).

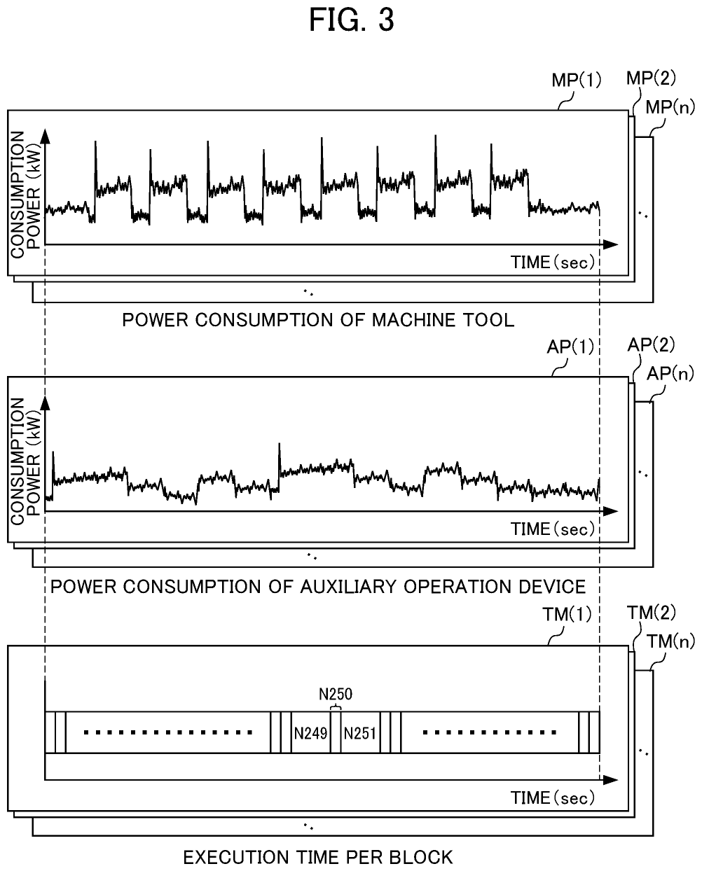

FIG. 3 is a diagram showing an example of power consumption information acquired as label data by the label acquisition unit 302.

The upper row of FIG. 3 shows the time series data MP(1) to MP(n) of the power consumption when the machine tool 10 of each piece of the machine tool information IM(1) to IM(n) shown in FIG. 2A runs each of the machining programs PG(1) to PG(n). The middle row of FIG. 3 shows the time series data AP (1) to AP (n) of the power consumption when the auxiliary operation device 102 of each piece of the auxiliary operation information IA(1) to IA(n) of FIG. 2B operates each of the machining programs PG(1) to PG (n). The lower row of FIG. 3 shows execution time data TM(1) to TM(n) indicating the execution time of each block of the machining programs PG(1) to PG(n) in FIG. 2C. In other words, FIG. 3 shows the auxiliary data necessary for calculating the label data.

It should be noted that the time series data MP(1) to MP(n) of the power consumption of the machine tool 10 of the upper row of FIG. 3 may be measured by a power meter (not shown) provided in the machine tool 10. Furthermore, the time series data AP(1) to AP(n) of the power consumption of the auxiliary operation device 102 of the middle of FIG. 3 may be measured by a power meter (not shown) provided in the auxiliary operation device 102. Furthermore, the execution time data TM(1) in the lower row of FIG. 3 indicates the execution times of the sequence numbers “N249”, “N250”, and “N251” among the blocks of the machining program PG(1).

More specifically, for example, the label acquisition unit 302 sums the maximum value of the power consumption of the machine tool 10 indicated by the time series data MP(1) and the maximum value of the power consumption of the auxiliary operation device 102 indicated by the time series data AP(1) in the execution time of the sequence number “N249” of the execution time data TM(1). The label acquisition unit 302 acquires, as label data, the summed values as the power consumption by the blocks of the sequence number “N249”. The label acquisition unit 302 also calculates the power consumption of the blocks of other sequence numbers in the same manner, and acquires the calculated power consumption as label data.

It should be noted that the label acquisition unit 302 sums the maximum value of the power consumption of the machine tool 10 at the execution time of the block as the power consumption of the block and the maximum value of the power consumption of the auxiliary operation device 102; however, the present invention is not limited thereto. For example, the label acquisition unit 302 may use the average or minimum value of the power consumption of the machine tool 10 and the auxiliary operation device 102 at the execution time of the block as the power consumption of the block.

In addition, the label acquisition unit 302 time-integrates the time series data MP(k) of the power consumption of the machine tool 10 of the machine tool information (k) and the time series data AP(k) of the power consumption of the auxiliary operation device 102 of the auxiliary operation information (k) from the start to the end of the execution of the machining program PG(k), and sums them to calculate the total power consumption (kWh) at the time of the running of the machining program, thereby acquiring the total power consumption (kWh) as the label data. It should be noted that k is a value from 1 to n.

The label acquisition unit 302 stores the label data acquired as described above in the storage unit 304.

The learning unit 303 receives the abovementioned set of the input data and the label as training data. The learning unit 303 uses the received training data to perform supervised learning, and constructs a learned model 250 that inputs machining information to be performed including the machine tool information of the machine tool 10, the auxiliary operation information of the auxiliary operation device 102, the workpiece information, and the machining information, and outputs the total power consumption amount at the time of the running of the machining program and the power consumption information in the machining to be performed including the power consumption of each block at the time of the running of the machining program.

Thereafter, the learning unit 303 provides the constructed learned model 250 to the power consumption prediction device 20.

It should be noted that it is preferable to prepare a number of pieces of training data for performing supervised learning. For example, training data may be acquired from machine tools 10 at various locations that are actually operating in a customer's factory or the like.

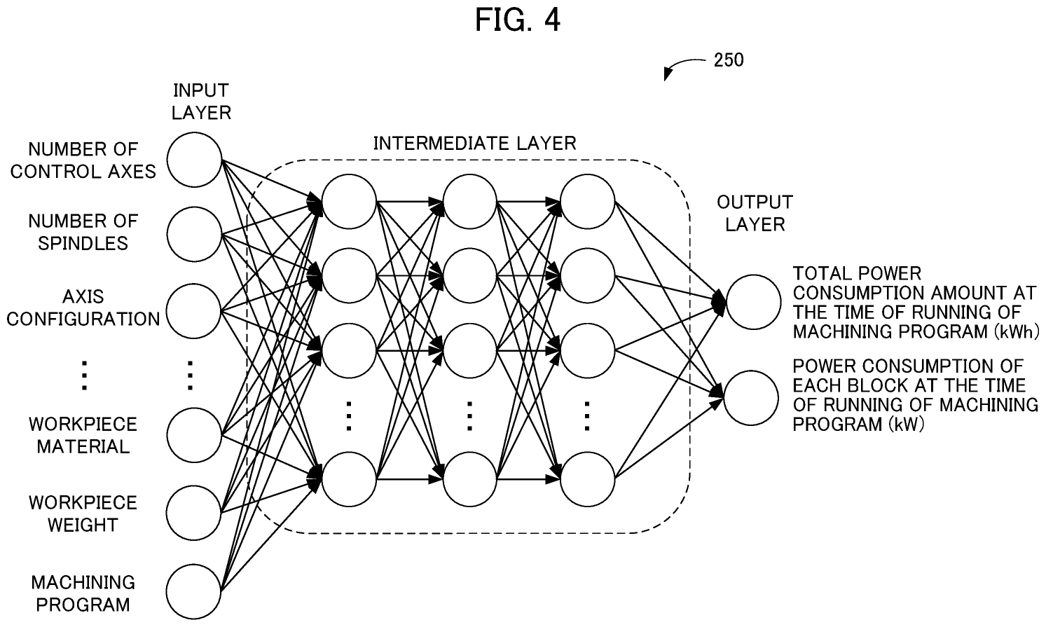

FIG. 4 is a diagram showing an example of a learned model 250 to be provided to the power consumption prediction device 20 of FIG. 1. Here, as shown in FIG. 4, the learned model 250 exemplifies a multi-layer neural network in which the machining information including the machine tool information of the machine tool 10, defining the auxiliary operation information of the auxiliary operation device 102, the workpiece information, and the machining program used as the input layers, and defining the total power consumption amount at the time of the running of the machining program and the power consumption of each block at the time of the running of the machining program as the output layers.

Here, the machine tool information of the machine tool 10 includes the number of control axes, the number of spindles, the axis configuration, and the positioning axis/spindle motor specifications (rated output (W), rated torque (N·m), etc.). Furthermore, the auxiliary operation information of the auxiliary operation device 102 includes the pump power (W) and power motor specifications (rated output (W), the rated torque (N·m), etc.). The workpiece information includes the material and weight of the workpiece.

Furthermore, when new training data are acquired after the learned model 250 is constructed, the learning unit 303 may update the learned model 250 that was constructed by performing further supervised learning for the learned model 250.

By doing so, since it is possible to obtain the training data automatically from the machining operation of the normal machine tool 10, it is possible to increase the prediction accuracy of the power consumption on a daily basis.

The abovementioned supervised learning may be performed by online learning. Moreover, the supervised learning may be performed by batch learning. Furthermore, the supervised learning may be performed by mini-batch learning.

Online learning refers to a learning method in which machining is performed in the machine tool 10, and supervised learning is immediately performed every time training data is generated. Batch learning refers to a learning method in which, while machining is performed in the machine tool 10 and training data is generated repeatedly, a plurality of pieces of training data corresponding to the repetition are collected, and supervised learning is performed using all the collected training data. Furthermore, mini-batch learning refers to a learning method which is intermediate between the online learning and the batch learning and in which the supervised learning is performed whenever a certain amount of training data is collected.

The storage unit 304 is RAM (Random Access Memory) or the like, and stores input data acquired by the input data acquisition unit 301, the label data acquired by the label acquisition unit 302, and the learned model 250 constructed by the learning unit 303.

The machine learning for generating the learned model 250 included in the power consumption prediction device 20 has been described above.

Next, the power consumption prediction device 20 in an operation phase will be described.

### <Power Consumption Prediction Device 20 in Operation Phase>

As shown in FIG. 1, the power consumption prediction device 20 in the operation phase is configured to include an input unit 201, a prediction unit 202, a determination unit 203, a notification unit 204, and a storage unit 205.

It should be noted that, in order to realize the operation of the functional blocks shown in FIG. 1, the power consumption prediction device 20 includes an arithmetic processing unit (not shown) such as a CPU (Central Processing Unit). Furthermore, the power consumption prediction device 20 includes an auxiliary storage device (not shown) such as a ROM (Read Only Memory) or a HDD (Hard Disk Drive) which stores various control programs, and a main storage device (not shown) such as RAM which stores data that is temporarily required for the arithmetic processor to execute the programs.

Furthermore, in the prediction device 20, the arithmetic processing device reads an OS or application software from the auxiliary storage device and expands the read OS and application software in the main storage device to perform arithmetic processing based on the read OS or application software. The power consumption prediction device 20 controls hardware components based on the arithmetic processing result. In this way, the processing of the functional blocks shown in FIG. 1 are realized. That is, the power consumption prediction device 20 can be realized by the cooperation of hardware and software.

Prior to the running of the machining program, the input unit 201 inputs the machining information including the machine tool information of the machine tool 10, the auxiliary operation information of the auxiliary operation device 102, the workpiece information, and a machining program to be operated from the machine tool 10. The input unit 201 outputs the inputted machining information to the prediction unit 202. The machining program to be run may be a newly created machining program or a machining program that has already been run.

It should be noted that the input unit 201 inputs, as the machining information, the machine tool ID for specifying the machine tool 10 as the machine tool information of the machine tool 10 included in the machining information and the auxiliary operation device ID for specifying the auxiliary operation device 102 as the auxiliary operation information of the auxiliary operation device 102. In this case, the machine tool information of the machine tool 10 associated with the machine tool ID and the auxiliary operation information of the auxiliary operation device 102 associated with the auxiliary operation device ID may be stored in advance in the storage unit 205 to be described later. Thus, the input unit 201 can acquire the machine tool information of the machine tool 10 and the auxiliary operation information of the auxiliary operation device 102 from the storage unit 205 based on the inputted machine tool ID and the auxiliary operation device ID.

The prediction unit 202 inputs the machine tool information of the machine tool 10, the auxiliary operation information of the auxiliary operation device 102, the workpiece information, and the machining program to be operated, which are included in the machining information inputted by the input unit 201, to the learned model 250 of FIG. 4, thereby acquiring the total power consumption amount at the time of the running of the machining program to be outputted by the learned model 250, and the power consumption of each block at the time of the running of the machining program outputted by the learned model 250. In so doing, it is possible for the prediction unit 202 to predict the total power consumption amount at the time of the running of the machining program, and the power consumption of each block at the time of the running of the machining program.

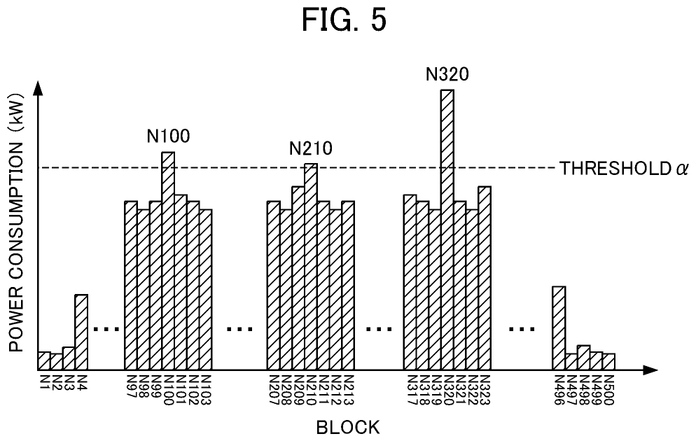

FIG. 5 is a diagram showing an example of a prediction result by the prediction unit 202.

The horizontal axis in FIG. 5 indicates the sequence number (block) of the machining program. The vertical axis in FIG. 5 shows the power consumption of each block predicted by the prediction unit 202.

As shown in FIG. 5, for example, it is indicated that there are blocks of sequence numbers “N100”, “N210”, and “N320” having the power consumption exceeding a threshold value α.

The determination unit 203 compares the power consumption of each block predicted by the predicting unit 202 with the threshold value α which is set in advance, and determines whether or not there is a block for which the power consumption exceeds the threshold value α. In a case in which there is no block for which the power consumption exceeds the threshold value α, the determination unit 203 determines to cause the machine tool 10 to machine the workpiece by operating the machining program without generating an alarm.

On the other hand, in a case in which there is a block for which the power consumption exceeds the threshold value α, the determination unit 203 determines to generate an alarm. The determination unit 203 outputs command block specifying information indicating the block (sequence number) for which the power consumption exceeds the threshold α to the notification unit 204 (to be described later).

In this way, it is possible for the power consumption prediction device 20 to urge the user of the machine tool 10 to review the machining program such as the machining conditions and machining paths so that the power consumption of the block is equal to or less than the threshold value α. That is, it is possible for the power consumption prediction device 20 to help the support of energy saving.

It should be noted that the threshold value α may be appropriately set in accordance with the cycle time, the machining accuracy, the power consumption, or the like required for the machine tool 10.

In a case in which the command block specifying information is received from the determination unit 203, the notification unit 204 may output the alarm and the sequence number indicated by the command block specifying information to an output device (not shown) such as a liquid crystal display included in the machine tool 10 and/or the control device 101. It should be noted that the notification unit 204 may be notified by voice through a speaker (not shown).

The storage unit 205 is ROM, an HDD, or the like, and may store the learned model 250 and the threshold value α together with various control programs. Furthermore, the storage unit 205 may store the machine tool information of the machine tool 10 associated with the machine tool ID and the auxiliary operation information associated with the auxiliary operation device ID.

<Prediction Processing of Power consumption Prediction Device 20 in Operation Phase>

Next, the operation relating to prediction processing of the power consumption prediction device 20 according to the present embodiment will described.

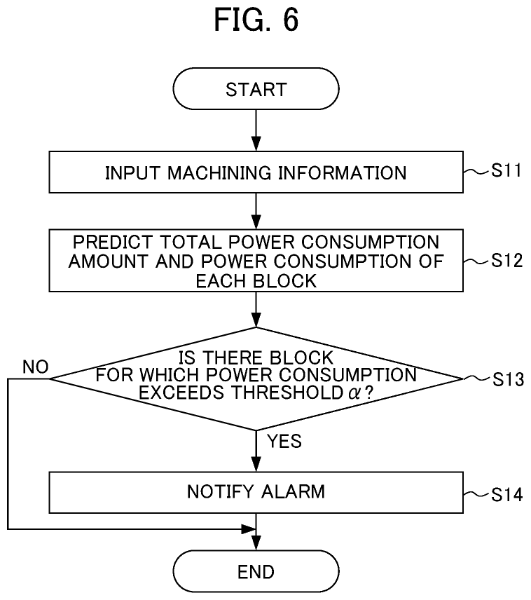

FIG. 6 is a flowchart for explaining the prediction processing of the power consumption prediction device 20 in the operation phase. The flow shown here is repeatedly executed every time the machining information is inputted.

In Step S11, prior to the running of the machining program, the input unit 201 inputs the machining information including the machine tool ID of the machine tool 10, the auxiliary operation device ID of the auxiliary operation device 102, the workpiece information, and a machining program to be run. For example, the input unit 201 acquires, from the storage unit 205, the machine tool information of the machine tool 10 associated with the inputted machine tool ID and the auxiliary operation information of the auxiliary operation device 102 associated with the inputted auxiliary operation device ID.

In Step S12, the prediction unit 202 inputs the machining information inputted in Step S11 to the learned model 250, thereby acquiring the total power consumption amount at the time of the running of the machining program and the power consumption information in the machining to be performed including the power consumption of each block at the time of the running of the machining program outputted by the learned model 250, and predicting the total power consumption amount at the time of the running of the machining program and the power consumption of each block at the time of the running of the machining program.

In Step S13, the determination unit 203 compares the power consumption of each block predicted in Step S12 with the threshold value α, and determines whether or not there is a block for which the power consumption exceeds the threshold value α. In a case in which there is a block for which the power consumption exceeds the threshold value α, the processing advances to Step S14. In a case in which there is no block for which the power consumption exceeds the threshold value α, the processing ends.

In Step S14, the notification unit 204 notifies the alarm determined in Step S13.

As described above, prior to the running of the machining program, the power consumption prediction device 20 according to an embodiment inputs the machining information including the machine tool information of the machine tool 10, the auxiliary operation information of the auxiliary operation device 102, the workpiece information, and a machining program to be run. The power consumption prediction device 20 inputs the inputted machining information to the learned model 250, thereby acquiring the total power consumption amount at the time of the running of the machining program and the power consumption information including the power consumption of each block at the time of the running of the machining program outputted by the learned model 250, and predicting the total power consumption amount at the time of the running of the machining program and the power consumption of each block at the time of the running of the machining program.

Thus, it is possible for the power consumption prediction device 20 to accurately predict the power consumption at the time of the running of the machining program without actually operating or simulating for power consumption measurement even when a newly created machining program is inputted.

More specifically, after the learning model is constructed, it is possible to estimate the power consumption of the machine tool 10 at the time of the running of the machining program without actually operating or simulating the newly created machining program for power consumption measurement.

Furthermore, as a secondary effect, tendency analysis of power consumption according to machining shapes and machining methods becomes easy. This leads to support for energy saving by reviewing the machining programs such as machining conditions and machining paths.

Furthermore, since it is possible to identify a block exceeding the threshold value α of the power consumption, by suppressing the peak power by changing the machining conditions around the block, it is also possible to support the reduction of the running cost for the facility by renewing the contract with the electric power company so as to maintain the minimum necessary amperage.

Although one embodiment has been described above, the power consumption prediction device 20 and the machine learning device 30 are not limited to the above-described embodiment, and includes modifications, improvements, and the like within a range in which the purpose thereof can be achieved.

### MODIFICATION EXAMPLE 1

In the above-described embodiment, the machine learning device 30 is exemplified as a device different from the machine tool 10, the control device 101, and the power consumption prediction device 20; however, the machine tool 10, the control device 101, or the power consumption prediction device 20 may be configured to include a portion or all of the functions of the machine learning device 30.

### MODIFICATION EXAMPLE 2

Furthermore, for example, in the above-described embodiment above, the power consumption prediction device 20 is exemplified as a device different from the machine tool 10 and the control device 101; however, the machine tool 10 or the control device 101 may be configured to include a portion or all of the functions of the power consumption prediction device 20.

Alternatively, for example, a server may be configured to include a portion or all of the input unit 201, the prediction unit 202, the determination unit 203, the notification unit 204, and the storage unit 205 of the power consumption prediction device 20. Moreover, the functions of the power consumption prediction device 20 may be realized using a virtual server function or the like on a cloud.

Furthermore, the power consumption prediction device 20 may be a distributed processing system in which each function of the power consumption prediction device 20 is distributed to a plurality of servers as appropriate.

### MODIFICATION EXAMPLE 3

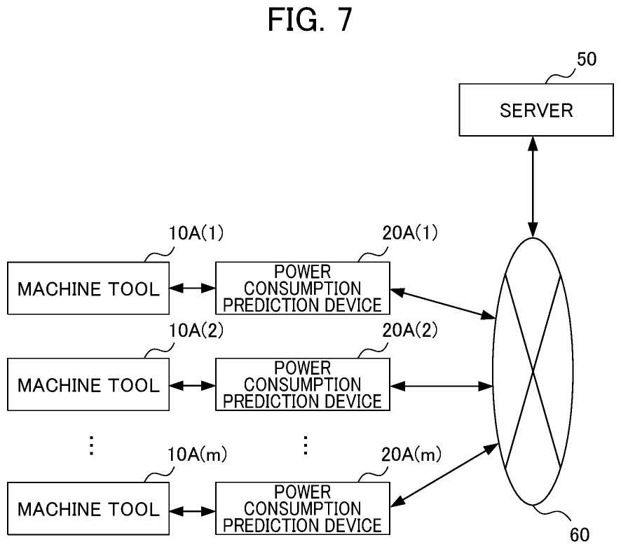

Furthermore, for example, in the above-described embodiment, the power consumption prediction device 20 uses the learned model 250 that inputs the machining information of the machining to be performed and outputs the power consumption information in the machining to be performed, which is provided from the machine learning device 30, thereby predicting the total power consumption amount at the time of the running of the machining program and the power consumption of each block at the time of the running of the machining program from the inputted machining information; however, the present invention is not limited thereto. For example, as shown in FIG. 7, the server 50 may store the learned model 250 generated by the machine learning device 30 and share the learned model 250 with m number of the power consumption prediction devices 20A(1) to 20A(m) connected to the network 60 (m is an integer of 2 or more). In this way, it is possible to adopt the learned model 250 even when a new machine tool and a new power consumption prediction device are installed.

It should be noted that the power consumption prediction devices 20A(1) to 20A(m) are respectively connected to the machine tools 10A(1) to 10A(m).

In addition, each of the machine tools 10A(1) to 10A(m) corresponds to the machine tool 10 of FIG. 1, may be a machine tool of the same model as each other, or alternatively, may be a machine tool of different models from each other. Each of the power consumption prediction devices 20A(1) to 20A(m) corresponds to the power consumption prediction device 20 of FIG. 1.

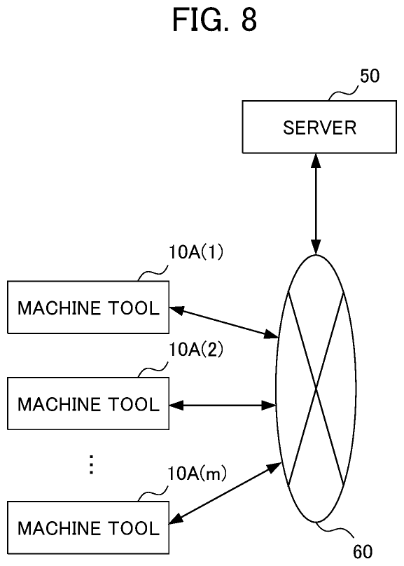

Alternatively, as shown in FIG. 8, the server 50 may, for example, operate as the power consumption prediction device 20, and predicts the total power consumption amount at the time of the running of the machining program from the inputted machining information, and the power consumption of each block at the time of the running of the machining program for each of the machine tools 10A(1) to 10A(m) connected to the network 60. This allows the learned model 250 to be adopted even when a new machine tool is installed.

### MODIFICATION EXAMPLE 4

Furthermore, for example, in the above-described embodiment, the power consumption prediction device 20 inputs the machining information shown in FIG. 4 to the learned model 250 that inputs the machining information of the machining to be performed and outputs the power consumption information in the machining to be performed, thereby acquiring the total power consumption amount at the time of the running of the machining program and the power consumption of each block at the time of the running of the machining program outputted by the learned model 250; however, the present invention is not limited thereto. For example, the power consumption prediction device 20 may acquire only the power consumption of each block at the time of the running of the machining program by inputting the machining information to the learned model 250.

### MODIFICATION EXAMPLE 5

Furthermore, for example, in the embodiment described above, although the machine learning device 30 performs supervised learning, the present invention is not limited thereto, and the learned model may be constructed by other learning methods, such as reinforcement learning for providing a +reward/−reward.

It should be noted that the functions included in the power consumption prediction device 20 and the machine learning device 30 in the embodiment can be realized by hardware, software, or a combination thereof. Here, being realized by software indicates being realized by a computer reading and executing programs.

Each of the components included in the power consumption prediction device 20 and the machine learning device 30 may be implemented by hardware, software, or a combination thereof including electronic circuits or the like. If implemented by software, the programs that constitute this software are installed to the computer. In addition, these programs may also be recorded on removable media and distributed to the user or downloaded to the user's computer over a network. Furthermore, when configured by hardware, a portion or all of the functions of each component included in the above-described devices can be constituted by an integrated circuit (IC) such as, for example, an ASIC (Application Specific Integrated Circuit), a gate array, an FPGA (Field Programmable Gate Array), a CPLD (Complex Programmable Logic Device), or the like.

The programs can be stored on any of various types of non-transitory computer readable media and provided to a computer. The non-transitory computer readable media include various types of tangible storage media. Examples of non-temporary computer readable media include magnetic recording media (e.g., flexible disks, magnetic tapes, hard disk drives), magneto-optical media (e.g., magneto-optical disks), CD-ROM (Read Only Memory), CD-R, CD-R/W, semiconductor memory (e.g., mask ROM, PROM (Programmable ROM), EPROM (Erasable PROM), flash ROM, and RAM. In addition, the programs may be provided to a computer by using any of various types of transitory computer readable media. Examples of the transitory computer readable media include electric signals, optical signals, and electromagnetic waves. A transitory computer readable medium can provide programs to a computer through a wired communication path such as electrical wires, optical fibers, or the like, or through a wireless communication path.

It should be noted that a step of writing programs to be recorded on a recording medium includes processing that is performed in a time series manner according to the order and processing that is performed in a parallel or independent manner even if the processing is not necessarily performed in a time series manner.

In other words, the machine learning device, the power consumption prediction device, and the control device of the present disclosure can have various embodiments having the following configurations.

(1) A machine learning device 30 includes: an input data acquisition unit 301 that, in machining of a workpiece with an arbitrary machine tool 10 by running of arbitrary machining programs PG(1) to (PG), acquires, as input data, at least information IM(1) to IM(n) relating to the machine tool 10, auxiliary operation information IA(1) to IA(n) relating to an auxiliary operation device 102 that performs an auxiliary operation of the machine tool 10, workpiece information relating to the workpiece, and machining information including the machining programs PG(1) to PG(n); a label acquisition unit 302 that acquires label data indicating power consumption information relating to power consumption of the machine tool 10 and the auxiliary operation device 102 in the running of the machining programs PG(1) to PG(n); and a learning unit 303 that performs supervised learning by using the input data acquired by the input data acquisition unit 301 and the label data acquired by the label acquisition unit 302, and generates a learned model 250 that inputs machining information of machining to be performed and outputs the power consumption information in the machining to be performed.

According to the machine learning device 30, it is possible to generate the learned model 250 that accurately outputs the power consumption by the operation of the newly created machining program without performing simulation.

(2) In the machine learning device 30 according to (1) above, the machine tool information IM(1) to IM(n) relating to the machine tool 10 may include at least one of a number of control axes, a number of spindles, an axis configuration, and a positioning axis/spindle motor specification, the auxiliary operation information IA(1) to IA(n) relating to the auxiliary operation device 102 may include at least one of pump power and a power motor specification, the workpiece information relating to the workpiece may include at least one of material and weight of the workpiece, and the information relating to the machining programs PG(1) to PG(n) may be program contents including a sequence number.

In so doing, it is possible to generate the learned model 250 which outputs the power consumption information corresponding to the machining information including the machine tool information of the machine tool 10, the auxiliary operation information of the auxiliary operation device 102, the workpiece information, and the machining program.

(3) In the machine learning device 30 according to (1) or (2) above, the power consumption information may include at least one of a total power consumption amount at a time of running of the machining programs PG(1) to PG(n) and power consumption of each block included in the machining programs PG(1) to PG(n) at the time of the running of the machining programs PG(1) to PG(n).

In this way, it is possible to generate the learned model 250 that outputs the total power consumption amount at the time of the running of the machining program according to the machining information of the machining to be performed and the power consumption of each block at the time of the running of the machining program.

(4) A power consumption prediction device 20 includes: a learned model 250 that is generated by the machine learning device 30 according to any one of (1) to (3), and inputs machining information of machining to be performed and outputs power consumption information in the machining to be performed; an input unit 201 that, prior to running of a machining program, inputs machining information including information relating to a machine tool 10, information relating to an auxiliary operation device 102 that performs an auxiliary operation of the machine tool 10, information relating to a workpiece as a machining target, and information relating to the machining program; and a prediction unit 202 that, by inputting the machining information inputted by the input unit 201 to the learned model 250, predicts power consumption information relating to power consumption at a time of running of the machining program based on the power consumption information in the machining to be performed outputted by the learned model 250.

According to the power consumption prediction device 20, it is possible to accurately predict the power consumption at the time of the running of the machining program even when a newly created machining program is inputted.

(5) In the power consumption prediction device 20 according to (4), the information relating to the machine tool 10 may include at least one of a number of control axes, a number of spindles, an axis configuration, and a positioning axis/spindle motor specification, the information relating to the auxiliary operation device 102 may include at least one of pump power and a power motor specification, the information relating to the workpiece may include at least one of material and weight of the workpiece, and the information relating to the machining program may be program contents including a sequence number.

In so doing, it is possible to predict the power consumption information at the time of the machining program running according to the machining information including the machine tool information of the machine tool 10, the auxiliary operation information of the auxiliary operation device 102, the workpiece information, and the machining program.

(6) In the power consumption prediction device 20 according to (4) or (5) above, the power consumption information may include at least one of a total power consumption amount at a time of running of the machining program and power consumption of each block included in the machining program at the time of the running of the machining program.

By doing so, it is possible to predict the total power consumption amount at the time of the running of the machining program and the power consumption of each block at the time of the running of the machining program.

(7) In the power consumption prediction device 20 according to any one of (4) to (6) above, the power consumption prediction device 20 further includes a storage unit 205 that stores in advance information relating to the machine tool 10 associated with a machine tool ID that identifies the machine tool 10, and information relating to the auxiliary operation device 102 associated with an auxiliary operation device ID that identifies the auxiliary operation device 102, in which, in a case in which the machine tool ID and the auxiliary operation device ID are inputted, the input unit 201 acquires the machine tool information relating to the machine tool 10 associated therewith and the auxiliary operation information relating to the auxiliary operation device 102 associated therewith from the storage unit 205.

By doing so, it is possible to easily acquire the machine tool information of the machine tool 10 and the auxiliary operation information of the auxiliary operation device 102 by inputting the machine tool ID and the auxiliary operation device ID.

(8) In the power consumption prediction device 20 according to (6) above, the power consumption prediction device 20 may further include a determination unit 203 that compares power consumption of each of the blocks at the time of the running of the machining program predicted by the prediction unit 202 with a threshold value α that is set in advance, and determines whether there is a block for which the power consumption exceeds the threshold value α.

By doing so, it is possible to urge the user of the machine tool 10 to review the machining program such as machining conditions and machining paths so that the power consumption of the block is equal to or less than the threshold value α, and it is possible to help supporting energy saving.

(9) In the power consumption prediction device 20 according to any one of (4) to (8) above, the learned model 250 may be included in a server 50 that is accessibly connected from the power consumption prediction device 20 via a network 60.

In so doing, the learned model 250 can still be adopted even when a new machine tool 10, control device 101, and power consumption prediction device 20 are deployed.

(10) In the power consumption prediction device 20 according to any one of (4) to (9), the power consumption prediction device 20 may further include the machine learning device 30 according to any one of (1) to (3) above.

With such a configuration, it is possible to exhibit advantageous effects similar to any of (1) to (9) described above.

(11) A control device 101 according to the present disclosure includes the power consumption prediction device 20 according to any one of (4) to (10) above.

According to the control device 101, it is possible to obtain effects similar to those of any of the above (4) to (10).

### EXPLANATION OF REFERENCE NUMERALS

1 prediction system

10 machine tool

101 control device

102 auxiliary operation device

20 power consumption prediction device

201 input unit

202 prediction unit

203 determination unit

204 communication unit

205 storage unit

250 learned model

30 machine learning device

301 input data acquisition unit

302 label acquisition unit

303 learning unit

304 storage unit

50 server

60 network

What is claimed is:

1. A machine learning device comprising:
an input data acquisition unit that, in machining of a workpiece with an arbitrary machine tool by running of an arbitrary machining program, acquires, as input data, at least information relating to the machine tool, information relating to an auxiliary operation device that performs an auxiliary operation of the machine tool, information relating to the workpiece, and machining information including the machining program;
a label acquisition unit that acquires label data indicating power consumption information relating to power consumption of the machine tool and the auxiliary operation device in the running of the machining program; and
a learning unit that performs supervised learning by using the input data acquired by the input data acquisition unit and the label data acquired by the label acquisition unit, and generates a learned model that inputs machining information of machining to be performed and outputs the power consumption information in the machining to be performed.

2. The machine learning device according to claim 1, wherein
the information relating to the machine tool includes at least one of a number of control axes, a number of spindles, an axis configuration, and a positioning axis/spindle motor specification,
the information relating to the auxiliary operation device includes at least one of pump power and a power motor specification,
the information relating to the workpiece includes at least one of material and weight of the workpiece, and
the information relating to the machining program is program contents including block specifying information.

3. The machine learning device according to claim 1, wherein the power consumption information includes at least one of a total power consumption amount at a time of running of the machining program and power consumption of each block included in the machining program at the time of the running of the machining program.

4. A power consumption prediction device comprising:
a learned model that is generated by the machine learning device according to claim 1, and inputs machining information of machining to be performed and outputs power consumption information in the machining to be performed;
an input unit that, prior to running of a machining program, inputs machining information including information relating to a machine tool, information relating to an auxiliary operation device that performs an auxiliary operation of the machine tool, information relating to a workpiece as a machining target, and information relating to the machining program; and
a prediction unit that, by inputting the machining information inputted by the input unit to the learned model, predicts power consumption information relating to power consumption at a time of running of the machining program based on the power consumption information in the machining to be performed outputted by the learned model.

5. The power consumption prediction device according to claim 4, wherein
the information relating to the machine tool includes at least one of a number of control axes, a number of spindles, an axis configuration, and a positioning axis/spindle motor specification,
the information relating to the auxiliary operation device includes at least one of pump power and a power motor specification,
the information relating to the workpiece includes at least one of material and weight of the workpiece, and the information relating to the machining program is program contents including block specifying information.

6. The power consumption prediction device according to claim 4, wherein the power consumption information includes at least one of a total power consumption amount at a time of running of the machining program and power consumption of each block included in the machining program at the time of the running of the machining program.

7. The power consumption prediction device according to claim 4, further comprising a storage unit that stores in advance information relating to the machine tool associated with a machine tool ID that identifies the machine tool, and information relating to the auxiliary operation device associated with an auxiliary operation device ID that identifies the auxiliary operation device,
wherein, in a case in which the machine tool ID and the auxiliary operation device ID are inputted, the input unit acquires the information relating to the machine tool associated therewith and the information relating to the auxiliary operation device associated therewith from the storage unit.

8. The power consumption prediction device according to claim 6, further comprising a determination unit that compares power consumption of each of the blocks at the time of the running of the machining program predicted by the prediction unit with a threshold value that is set in advance, and determines whether there is a block for which the power consumption exceeds the threshold value.

9. The power consumption prediction device according to claim 4, wherein the learned model is included in a server that is accessibly connected from the power consumption prediction device via a network.

10. The power consumption prediction device according to claim 4, further comprising the machine learning device according to claim 1.

11. A control device comprising the power consumption prediction device according to claim 4.
